(19) United States
(12) Patent Application Publication
(10) Pub. No.: US 2025/0218887 A1
(43) Pub. Date: Jul. 3, 2025

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventors: Kohei YAMAUCHI, Hachioji-City (JP); Hideki IWATA, Hino-City (JP); Eiji MOCHIZUKI, Matsumoto-city (JP); Yoshitaka NISHIMURA, Azumino-city (JP); Yuji HAYASE, Akishima-city (JP); Hiroto WATANABE, Mitaka-city (JP)

(21) Appl. No.: 18/957,835

(22) Filed: Nov. 24, 2024

(30) Foreign Application Priority Data
Dec. 28, 2023 (JP) 2023-222513

(51) Int. Cl. H01L 23/31; H01L 23/00

(52) U.S. Cl. CPC H01L 23/3157; H01L 23/3107; H01L 24/16; H01L 2224/16225

(57) ABSTRACT

Provided is a semiconductor device, comprising: a switching device having a first main electrode on one surface; a connection conductor that is connected to the first main electrode of the switching device; an encapsulating portion that encapsulates a space between the switching device and the connection conductor; and an insulation layer arranged to overlap with the encapsulating portion between at least a part of the switching device and the connection conductor.

The contents of the following patent application(s) are incorporated herein by reference:
NO. 2023-222513 filed in JP on Dec. 28, 2023

### BACKGROUND

### 1. Technical Field

The present invention relates to a semiconductor device, and manufacturing method of the semiconductor device.

### 2. Related Art

Patent document 1 describes that “In the semiconductor module 100 including the semiconductor assembly 110 including a plurality of semiconductor chips 30, it is possible to constitute an inverter, or a power device such as an IPM (Intelligent Power Module) including a control circuit, as a whole.” (Paragraph 0031), “As an example, the PCB 40 is electrically connected to a semiconductor chip 30 by a bonding wire 55.” (Paragraph 0032), “The external connection section 50 may be subjected to nickel plating. By connecting a copper bus bar to the external connection section 50, it is possible to apply a large current to each main terminal 52 of the semiconductor assembly 110.” (Paragraph 0033), and “The semiconductor assembly 110 may have a metal wiring plate 70 which electrically connects the semiconductor chip 30 and the main terminal 52. Instead of the metal wiring plate 70, the semiconductor chip 30 and the main terminal 52 may be electrically connected by a conductive member such as a wire or a ribbon.” (Paragraph 0035).

Patent document 2 describes that “Two semiconductor devices 3 are electrically connected by a wiring member W1. One of the two semiconductor devices 3 is electrically connected to a second circuit layer 24 via a wiring member 2. The second circuit layer 24 is electrically connected to an external terminal 27 described below via a wiring member 3. Another of the two semiconductor devices 3 is electrically connected to a third circuit layer 25 via a wiring member 4. The third circuit layer 25 is electrically connected to another external terminal 27 via a wiring member 5.” (Paragraph 0023), “Note that a conducting wire is used for each of the above wiring members. Gold, copper, aluminum, gold alloy, copper alloy, and aluminum alloy can be used as either singly or in combination with each other as the material of the conducting wires. It is also possible to use a member other than conducting wires as the wiring members. For example, ribbons can be used as the wiring members.” (Paragraph 0024), and “The insulating circuit substrate 2 and the semiconductor devices 3 are covered by a case 11 that acts a housing enclosing the perimeter. The case 11 includes an annular wall part 12 that encloses an outer perimeter side of the insulating circuit substrate 2 and a lid part 13 that covers the tops of the insulating circuit substrate 2 and the semiconductor devices 3, and is formed using a synthetic resin for example.” (Paragraph 0025).

### PRIOR ART DOCUMENT

### Patent Document

Patent Document 1: Japanese Patent Application Publication No. 2021-002610

Patent Document 2: International Publication No. 2020/121680

### BRIEF DESCRIPTION OF THE DRAWINGS

FIG. 1 is a perspective view of a switching device 10 according to the present embodiment.

FIG. 2 is a cross section of a semiconductor device 200 according to a reference example.

FIG. 3 is a cross section of a semiconductor device 200 according to the present embodiment.

FIG. 4 is a cross section of a semiconductor device 200 according to a first modification example of the present embodiment.

FIG. 5 is a perspective view of the semiconductor device 200 according to the present embodiment.

FIG. 6 shows a manufacturing method of the semiconductor device 200 according to the present embodiment.

FIG. 7 is a perspective view of a configuration in which a switching device 10 and a second main electrode plate 230 are bonded to each other according to the present embodiment. FIG. 8 is a perspective view of a mounting substrate 210 according to the present embodiment.

FIG. 9 shows a state in which an insulation layer 280 is arranged on the mounting substrate 210 according to the present embodiment.

FIG. 10 is a perspective view of a configuration in which the switching device 10 to which the second main electrode plate 230 is bonded is bonded to the mounting substrate 210 according to the present embodiment.

FIG. 11 is a perspective view of a configuration in which a first main electrode plate 220, a control electrode plate 240, and a sub-electrode plate 250 are bonded to the mounting substrate 210 according to the present embodiment.

FIG. 12 shows a state in which an insulation layer 280 is arranged on the mounting substrate 210 according to a second modification example of the present embodiment.

FIG. 13 is a cross section of a semiconductor device 200 according to a third modification example of the present embodiment.

FIG. 14 shows a state in which an insulation layer 280 is arranged on the mounting substrate 210 according to a fourth modification example of the present embodiment.

FIG. 15 shows a state in which a boundary wall 290 is arranged on the mounting substrate 210 according to a fifth modification example of the present embodiment.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

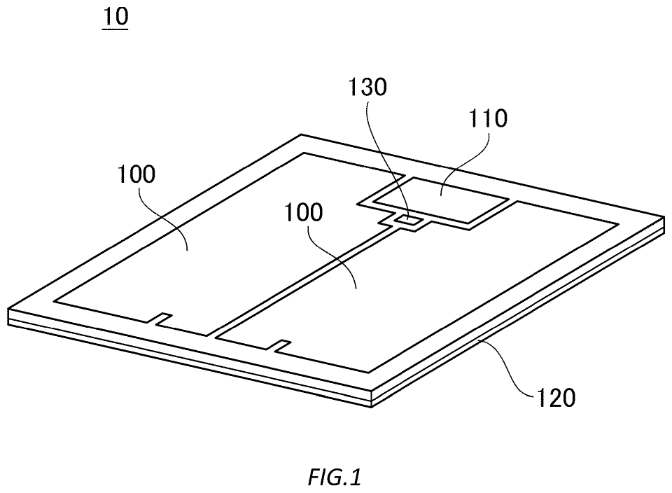

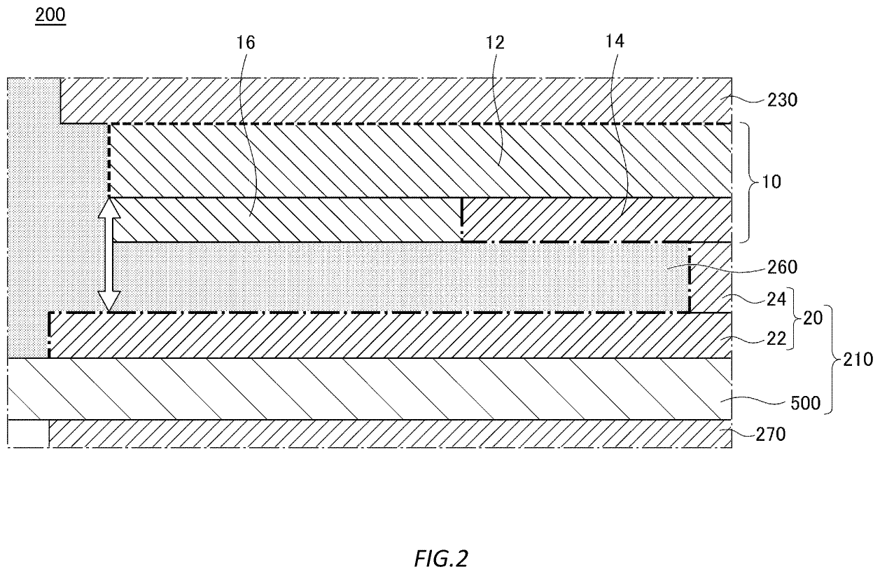

FIG. 1 is a perspective view of a switching device 10 according to the present embodiment. The switching device 10 is a semiconductor switching device such as a MOSFET (Metal-Oxide-Semiconductor Field-Effect Transistor). The switching device 10 may be a power MOSFET of a vertical structure. The switching device 10 may be an Si semiconductor device such as Si-MOSFET, may be a SiC semiconductor device such as an SiC-MOSFET capable of faster switching, and may be a device using a wide gap semiconductor such as GaN, diamond, gallium nitride based material, gallium oxide based material, AIN, AIGaN, or ZnO. Alternatively, the switching device 10 may be a semiconductor switch device such as an IGBT (Insulated Gate Bipolar Transistor), or may be a SiC-IGBT. In addition, the switching device 10 may be an HEMT (High-Electron-Mobility Transistors).

The switching device 10 may be a semiconductor chip, has a first main electrode 100 and a control electrode 110 on one surface (a surface on the upper side in the figure), and has a second main electrode 120 on the opposite surface. In the example of the present drawing, the switching device 10 further has a sensing electrode 130 on a surface on the upper side in the figure. In a case in which the switching device 10 is a MOSFET, the switching device 10 has a source and a drain as a first main electrode 100 and a second main electrode 120, has a gate as a control electrode 110, and has a sense source as a sensing electrode 130. In a case in which the switching device 10 is an IGBT, the switching device 10 has an emitter and a collector as a first main electrode 100 and a second main electrode 120, has a gate as a control electrode 110, and has a sense emitter as a sensing electrode 130. In the present embodiment, for convenience of description, the case in which the switching device 10 is a MOSFET is shown.

Note that the names of “first main electrode” and “second main electrode” are given to distinguish between two main electrodes included in a switching device 10, for convenience of description. Accordingly, the switching device 10 may be considered as a switching device having a sign 100 that is the second main electrode and a control electrode 110 on one surface, and having a sign 120 that is the first main electrode on the opposite surface. In addition, a switching device 10 used for a semiconductor device 200 shown below may take a configuration in which a second main electrode 120 does not exist on a surface opposite to a first main electrode 100, or may have a second main electrode 120 on a surface on a side closer to a first main electrode 100.

FIG. 2 is a cross section of a semiconductor device 200 according to a reference example. A semiconductor module using a switching device such as the switching device 10 shown in FIG. 1 generally takes a structure in which one surface of the switching device (for example, a surface on a side closer to a second main electrode 120) is bonded to a wiring pattern on a substrate, and each electrode of another surface (for example, a first main electrode 100, a control electrode 110, and a sensing electrode 130) is electrically connected to another wiring pattern by wire bonding. Such a semiconductor module is formed as an integrated module by resin encapsulating of: a substrate on which a switching device is mounted; each bonding wire; a positive electrode terminal; a negative electrode terminal; and each metal plate on which an output terminal is connected.

In contrast, in a semiconductor device 200 according to a reference example, one surface of the switching device 10 (for example, a surface on a side closer to the second main electrode 120) can be bonded to a wiring pattern on a substrate outside the semiconductor device 200 by exposing the surface to a surface of the semiconductor device 200 directly or via a second main electrode plate 230, and each electrode on another surface side closer to the switching device 10 (for example, the first main electrode 100, the control electrode 110, and the sensing electrode 130) is directly connected to a connection conductor such as a wiring pattern provided on the substrate in the semiconductor device 200. Such a connection conductor electrically connects each electrode on another surface side closer to the switching device 10 to an external electrode such as an electrode plate that is exposed outside the semiconductor device 200. Alternatively, the semiconductor device 200 may take a structure in which a surface on a side closer to the first main electrode 100, the control electrode 110, and the sensing electrode 130 is exposed on the surface of the semiconductor device 200, and the surface on the side closer to the second main electrode 120 is directly connected to the connection conductor. By such a structure, the semiconductor device 200 can be thinned because each electrode of the switching device 10 is no longer required to be connected by the wire bonding inside the semiconductor device 200. In addition, by using such a semiconductor device 200, a thinner or miniaturized semiconductor module can be attained.

The semiconductor device 200 according to the reference example includes a switching device 10, a mounting substrate 210, a second main electrode plate 230, and an encapsulating portion 260. In the present drawing, the switching device 10 has the surface on the side closer to the first main electrode 100, etc. arranged downward in the figure, and the surface on the side closer to the second main electrode 120 arranged upward in the figure. The switching device 10 has a device structure including a metal film 14, an interlayer dielectric film 16, and the like on a chip substrate 12 (lower side in the figure) in the cross section. Note that in the present drawing, a part in a device structure that is to be formed on the chip substrate 12, the part being focused in this application, is mainly shown, and illustration and description of a structure with more detail will be omitted.

The metal film 14 is exposed on one surface of the switching device 10 (a surface on the lower side in the figure), and functions as an electrode of the switching device 10. In the example of the present drawing, the metal film 14 may be the first main electrode 100 of FIG. 1.

Alternatively, the metal film 14 may be the control electrode 110, or may be the sensing electrode 130. In addition, the metal film 14 may be the second main electrode 120 of FIG. 1.

The interlayer dielectric film 16 is a dielectric film that is obtained by, for example, a silicon oxide film, a silicon nitride film, or the like formed integrally with a switching device 10 by using a semiconductor process during manufacturing of the switching device 10. The interlayer dielectric film 16 may be formed to be integrated with the switching device 10 before singulation of the switching device 10 during a semiconductor process for manufacturing the switching device 10.

The mounting substrate 210 mounts the switching device 10 on a mounting surface (a surface on the upper side in the figure). The mounting substrate 210 has an insulating substrate 500, and a connection conductor 20 formed on the mounting surface of the switching device 10 on the insulating substrate 500. The connection conductor 20 is connected to the first main electrode 100 of the switching device 10. The connection conductor 20 may include a conductor pattern 22, and one or more pillars 24. The conductor pattern 22 may be formed on the insulating substrate 500 by a conductive metal film or a conductive metal plate made of copper or the like.

As an example, the conductor pattern 22 is a wiring pattern for connection between the external electrode and the switching device 10 arranged at a position that does not overlap with the chip substrate 12 in a top view of the semiconductor device 200. One or more pillars 24 are arranged in a region facing the metal film 14 in the conductor pattern 22, and connect the conductor pattern 22 to the metal film 14 by contacting the metal film 14. The pillar 24 is formed by a conductive metal. In the example of the present drawing, the pillar 24 is a pillar with cylindrical shape or the like. In the example of the present drawing, the pillar 24 is used, but a projection (bump) of any shape without being limited to the pillar may be used.

The mounting substrate 210 may have a heat conductor plate 270 formed on a surface on a side opposite to the mounting surface of the switching device 10 on the insulating substrate 500. The heat conductor plate 270 may be a thermal conduction component such as a copper sheet, having a thermal conductivity that is higher than that of the insulating substrate 500.

The second main electrode plate 230 is electrically connected to the second main

electrode 120 of the switching device 10. The encapsulating portion 260 encapsulates a space between the switching device 10 and the connection conductor 20. The encapsulating portion 260 may be formed by implanting and curing a resin material such as epoxy or silicon, for example, between the switching device 10 and the connection conductor 20.

The semiconductor device 200 can be thinned by the configuration described above. However, depending on an application destination to which the semiconductor module using the semiconductor device 200 is applied, a high voltage such as hundreds of V or one thousand and hundreds of V may be applied between main electrodes of the switching device 10. Herein, because a surface on a second main electrode plate 230 side in the switching device 10 and an outer edge portion of the switching device 10 (that is, an outer edge portion of the chip substrate 12) has a potential that is approximately the same as that of the second main electrode 120, and the connection conductor 20 has a potential approximately the same as that of the first main electrode 100, as shown with the arrow in the figure, insulating property between the outer edge portion of the switching device 10 (more specifically, an edge on a side closer to an connection conductor 20 in a side surface of the chip substrate 12), the connection conductor 20 or the like becomes a problem. For example, in a case in which a distance between the switching device 10 and the conductor pattern 22 is dozens of um to one hundred and dozens of um or the like due to the semiconductor device 200 being thinned, an insulation distance may be insufficient only by separating the outer edge portion of the chip substrate 12 and the conductor pattern 22 with the encapsulating portion 260.

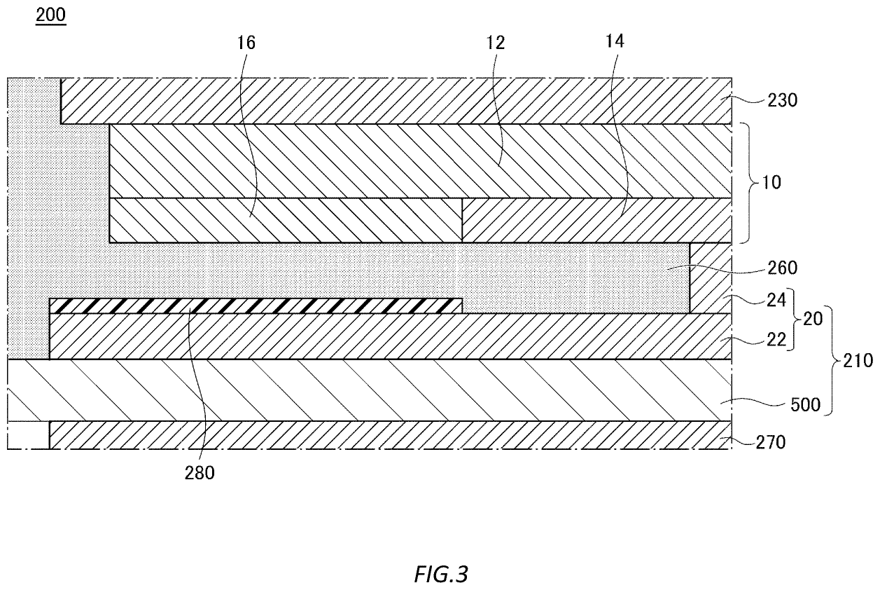

FIG. 3 is a cross section of a semiconductor device 200 according to the present embodiment. Because the semiconductor device 200 shown in the present drawing is obtained by adding an insulation layer 280 to the semiconductor device 200 of the reference example shown in FIG. 2, descriptions will be omitted except for the following differences.

The semiconductor device 200 according to the present embodiment includes an insulation layer 280 arranged to overlap with the encapsulating portion 260 between at least a part of the switching device 10 and the connection conductor 20. The insulation layer 280 may be arranged between the outer edge portion and the connection conductor 20 in the entire outer edge portion of the switching device 10, or may be arranged between the outer edge portion and the connection conductor 20 in at least a part of the outer edge portion of the switching device 10.

The insulation layer 280 may be arranged between at least a part whose potential difference between the connection conductor 20 on the surface on a side closer to the first main electrode 100 of the switching device 10 exceeds a predetermined voltage limit (for example, a part having the same potential as that of the second main electrode 120) and the connection conductor 20. In the example of the present drawing, the insulation layer 280 is stacked on a surface on a side in the connection conductor 20 that is closer to a switching device 10.

The insulation layer 280 may be formed by a material having an electrical resistivity higher than that of an encapsulation material of the encapsulating portion 260. As an example, the insulation layer 280 may be a layer, a film, and a sheet (for example, an insulating adhesive sheet) having polyimide, polyester, liquid crystal polymer, and the like, or at least one of them as a base material. The insulation layer 280 may have a thickness of ½ or less or ¼ or less of a distance between the outer edge portion of the switching device 10 and the connection conductor 20. By reducing a thickness of the insulation layer 280, the encapsulation material can be easily flown into a gap between the switching device 10 and the connection conductor 20. The insulation layer 280 may have a thickness of 1/20 or more, 1/10 or more, or ⅛ or more of the distance between the outer edge portion of the switching device 10 and the connection conductor 20. By using a material of high electrical resistivity as the insulation layer 280, sufficient insulating property can be obtained even if the thickness of the insulation layer 280 is relatively small.

A range in which the insulation layer 280 is provided may be defined according to a structure and a requested breakdown voltage of the semiconductor device 200. The range in which the insulation layer 280 is provided may be determined provided that whether a total of a distance between the outer edge portion of the switching device 10 and the insulation layer 280 and a creepage distance from a place directly below the outer edge portion of the switching device 10 on the insulation layer 280 leading to the conductor pattern 22 by passing through the surface of the insulation layer 280 is a sufficient insulation distance for the requested breakdown voltage. In the example of the present drawing, such a creepage distance may be a length of the shortest path among paths from a place directly below the outer edge portion of the switching device 10 in the encapsulating portion 260 leading to an exposed section of the insulation layer 280 in the conductor pattern 22 (in the example of the present drawing, an upper surface portion of the conductor pattern 22 exposed from the insulation layer 280 on a right end side closer to the insulation layer 280, and a side surface portion of the conductor pattern 22 exposed from the insulation layer 280 on a left end side closer to the insulation layer 280) by passing through the surface of the encapsulating portion 260. In addition, in a case in which a length of a path from the place directly below the outer edge portion of the switching device 10 in the encapsulating portion 260 leading to an exposed section from the insulation layer 280 in the conductor pattern 22 of the encapsulating portion 260 on the right end in the figure by passing through the surface of the encapsulating portion 260 is relatively short, in a case in which a length of this path is the creepage distance, a sufficient insulation distance is required to exist.

In addition, the insulation layer 280 may be arranged to face a region including from at least a part of the outer edge portion in the switching device 10 to an outer edge portion of a conductor exposed to a surface on a side closer to a connection conductor 20 of the switching device 10 (for example, a metal film 14). In the example of the present drawing, because the metal film 14 is connected to the connection conductor 20, potentials of the metal film 14 and the connection conductor 20 are substantially the same. Accordingly, the metal film 14 and the conductor pattern 22 may not have an insulation layer 280 arranged therebetween.

In addition, in a case in which the switching device 10 is a vertical semiconductor device

such as a power MOSFET or an IGBT, a guard ring enclosing a device structure provided on the surface on the side closer to the connection conductor 20 is provided in the vicinity of the outer edge portion of the surface on the side closer to the connection conductor 20 in the chip substrate 12. In the surface on the side closer to the connection conductor 20 of the switching device 10, a region outside the guard ring may become a substantially same potential as that of a surface on the opposite side in the switching device 10. Therefore, the insulation layer 280 may be arranged to face a region including from at least a part of the outer edge portion in the switching device 10 to the guard ring of the switching device 10. Note that it is enough for the insulation layer 280 to be arranged in a required minimal range in which an insulating property can be secured, and the insulation layer 280 may be provided in a range smaller than the range described above as long as a requested insulating property can be secured.

According to the semiconductor device 200 described above, the insulating property between the switching device 10 and the connection conductor 20 can be sufficiently secured while the semiconductor device 200 is thinned.

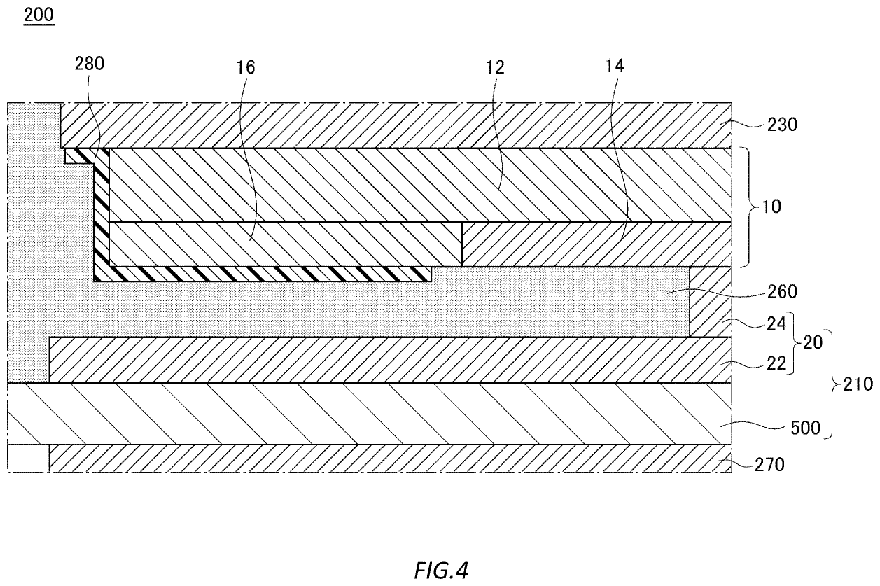

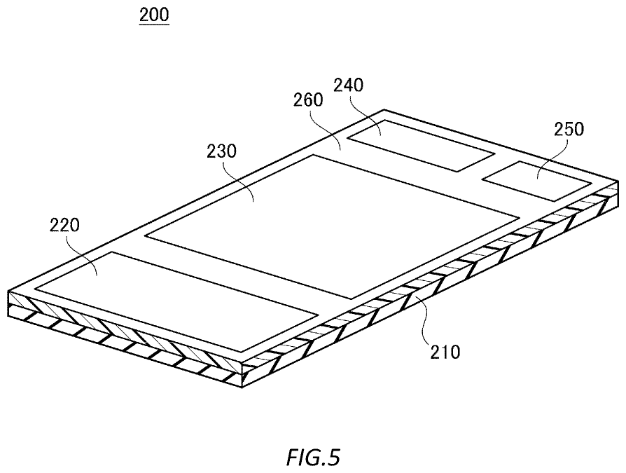

FIG. 4 is a cross section of a semiconductor device 200 according to a first modification example of the present embodiment. Because the semiconductor device 200 shown in the present drawing is a modification example of the semiconductor device 200 shown in FIG. 3, descriptions will be omitted except for the following differences. Similar to the semiconductor device 200 shown in FIG. 3, the semiconductor device 200

according to the present modification example includes an insulation layer 280 arranged to overlap with the encapsulating portion 260 between the outer edge portion of the switching device 10 and the connection conductor 20. The insulation layer 280 may be arranged between the outer edge portion and the connection conductor 20 in the entire outer edge portion of the switching device 10, or may be arranged between the outer edge portion and the connection conductor 20 in at least a part of the outer edge portion of the switching device 10. In the present modification example, the insulation layer 280 is stacked on the surface on the side closer to the connection conductor 20, in the switching device 10.

In the present modification example, the insulation layer 280 entirely covers the side surface of the switching device 10 in a thickness direction of the switching device 10, to secure the insulation distance between an outer edge portion of the switching device 10 and the connection conductor 20. Alternatively, as long as a sufficient insulation distance can be secured, the insulation layer 280 may cover only a range of at least a part of the side of the switching device 10 that is closer to the connection conductor 20 on the side surface in the thickness direction of the switching device 10. Similar to the semiconductor device 200 of FIG. 3, the thickness of the insulation layer 280, and the range in which the insulation layer 280 is provided may be defined according to a structure and a requested breakdown voltage of the semiconductor device 200.

FIG. 5 is a perspective view of the semiconductor device 200 according to the present embodiment. The semiconductor device 200 according to the present embodiment has a structure in which each electrode plate electrically connected to each electrode of the switching device 10 is exposed to one surface of a semiconductor device 200 that is plate-shaped. In the present embodiment, the semiconductor device 200 includes a mounting substrate 210, a first main electrode plate 220, a second main electrode plate 230, a control electrode plate 240, a sub-electrode plate 250, and an encapsulating portion 260.

The mounting substrate 210 mounts the switching device 10 on a mounting surface (a surface on the upper side in the figure). The first main electrode plate 220 is electrically connected to a first main electrode 100 of the switching device 10. The second main electrode plate 230 is electrically connected to a second main electrode 120 of the switching device 10. The control electrode plate 240 is electrically connected to a control electrode 110 of the switching device 10. The sub-electrode plate 250 is electrically connected to the first main electrode 100 of the switching device 10. Herein, the first main electrode plate 220, the second main electrode plate 230, the control electrode plate 240, and the sub-electrode plate 250 are exposed to a surface opposite to a side on mounting substrate 210 in the semiconductor device 200 (a switching device 10 mounting surface side on the mounting substrate 210). The encapsulating portion 260 coats the mounting surface of the switching device 10 on the mounting substrate 210 while exposing the first main electrode plate 220, the second main electrode plate 230, the control electrode plate 240, and the sub-electrode plate 250.

Instead of modularizing the switching device such as the switching device 10 as previously described, by bonding each electrode plate of one surface of the semiconductor device 200 to a wiring pattern on a substrate by using the semiconductor device 200 of the present embodiment, all required electrodes in the switching device 10 can be electrically connected to wiring on the substrate without wire bonding.

Note that the semiconductor device 200 may further have an electrode plate electrically connected to a sensing electrode 130 on a same surface as that of the first main electrode plate 220 or the like. In addition, both the first main electrode plate 220 and the sub-electrode plate 250 are electrically connected to the first main electrode 100 of the switching device 10, but the first main electrode plate 220 is used for flowing a large current due to its large area, and the sub-electrode plate 250 is used for controlling the switching device 10 as a pair with the control electrode plate 240. In another form, the semiconductor device 200 may not include the sub-electrode plate 250, and in this case, the first main electrode plate 220 is used for controlling the switching device 10.

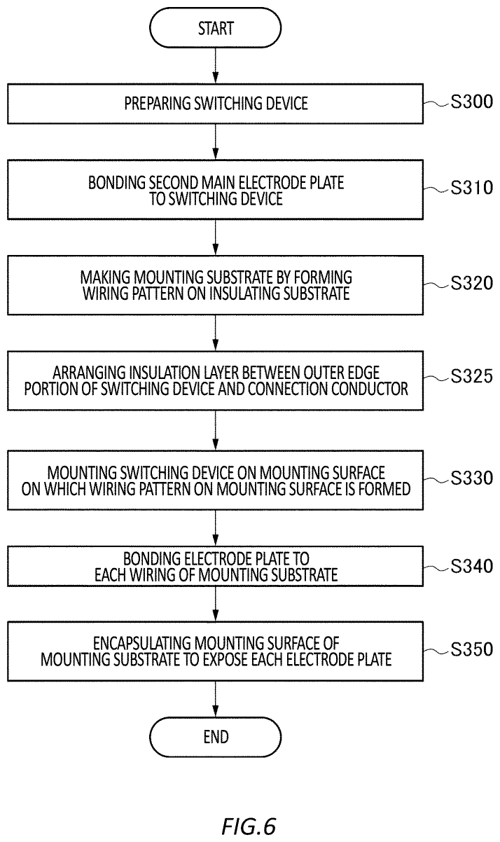

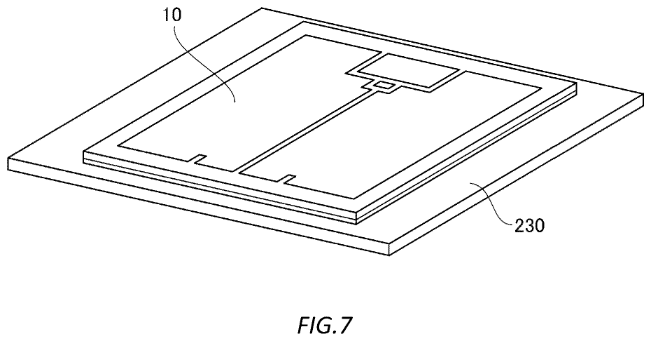

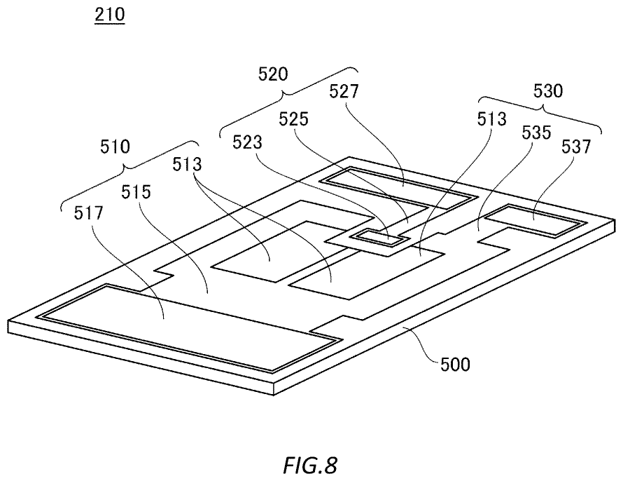

FIG. 6 shows a manufacturing method of the semiconductor device 200 according to the present embodiment. Hereinafter, a manufacturing method of the semiconductor device 200 is described referring to FIG. 7 to FIG. 11 showing configurations during manufacturing of the semiconductor device 200. In S300 (step 300), a switching device 10 having a first main electrode 100 and a control electrode 110 on one surface, and having a second main electrode 120 on an opposite surface is prepared.

In S310, a second main electrode plate 230 is bonded on a surface on a side closer to second main electrode 120 of the switching device 10. FIG. 7 is a perspective view of a configuration in which a switching device 10 and a second main electrode plate 230 are bonded to each other according to the present embodiment. The second main electrode plate 230 is a conductive plate such as a copper sheet. The second main electrode plate 230 may be bonded to the second main electrode 120 by using a sintering agent of nano-silver, or may be bonded by directly bonding between gold and gold. In this way, the second main electrode plate 230 is electrically connected to the second main electrode 120 of the switching device 10. In addition to the descriptions above, the second main electrode plate 230 may be bonded by a solder material, or bonded by directly bonding between copper and copper. In addition, a plurality of bumps arrayed regularly or randomly on the second main electrode plate 230 may be bonded to a second main electrode of the switching device 10.

In S320, a mounting substrate 210 is made. FIG. 8 is a perspective view of a mounting substrate 210 according to the present embodiment. In this process, a mounting substrate 210 having wiring patterns of a first main electrode wiring 510, a control wiring 520, and a sub-wiring 530 is made on a mounting surface on which a switching device 10 on an insulating substrate 500 such as Si, silicon nitride, or aluminum nitride is to be mounted. The insulating substrate 500 may create components including the above-described components by using a ceramic material or the like.

A first main electrode wiring 510 is formed by a conductive metal film or a conductive metal plate such as copper. The first main electrode wiring 510 is an example of the connection conductor 20 of FIG. 2 to FIG. 4. The first main electrode wiring 510 includes a first main electrode contact 513, a wiring 515, and a first main electrode plate contact 517. The first main electrode contact 513 is an area that is connected to the first main electrode 100 of the switching device 10. The wiring 515 corresponds to the conductor pattern 22 of FIG. 2 to FIG. 4, and electrically connects between the first main electrode contact 513 and the first main electrode plate contact 517. The first main electrode plate contact 517 is an area that is connected to the first main electrode plate 220.

Similar to the first main electrode wiring 510, the control wiring 520 is formed by a conductive metal film or a conductive metal plate such as copper. The control wiring 520 includes a control electrode contact 523, a wiring 525, and a control electrode plate contact 527. The control electrode contact 523 is an area that is connected to the control electrode 110 of the switching device 10. The wiring 525 electrically connects between the control electrode contact 523 and the control electrode plate contact 527. The control electrode plate contact 527 is an area that is connected to the control electrode plate 240. The control wiring 520 may be handled as the connection conductor 20 of FIG. 2 to FIG. 4.

Similar to the first main electrode wiring 510, the sub-wiring 530 is formed by a conductive metal film or a conductive metal plate such as copper. The sub-wiring 530 includes a first main electrode contact 513, a wiring 535, and a sub-electrode plate contact 537. The first main electrode contact 513 is shared with the first main electrode wiring 510. The sub-wiring 530 may utilize a part of the first main electrode contact 513 that is used by the first main electrode wiring 510. The wiring 535 electrically connects between the first main electrode contact 513 and the sub-electrode plate contact 537. The wiring 535 may have a smaller wiring width compared to that of the wiring 515. The sub-electrode plate contact 537 is an area that is connected to the sub-electrode plate 250. The sub-wiring 530 may be handled as the connection conductor 20 of FIG. 2 to FIG. 4.

Herein, a region bonded to each electrode of the switching device 10 such as the first main electrode contact 513 and the first main electrode plate contact 517 of the first main electrode wiring 510, the control electrode contact 523 and the control electrode plate contact 527 of the control wiring 520, and the sub-electrode plate contact 537 of the sub-wiring 530 or each electrode plate such as the first main electrode plate 220, the second main electrode plate 230, the control electrode plate 240, and the sub-electrode plate 250 may have a plurality of bumps, each of which being regular or randomly arrayed. The pillar 24 shown in FIG. 2 to FIG. 4 is an example of such bumps. These plurality of bumps may be bumps of conductive metal such as gold, for example. These plurality of bumps may be formed by arranging a bump precursor of conductive metal in each region by transferring or the like, and firing and curing the bump precursor, for example.

In S325, in entire or at least a part of the outer edge portion of the switching device 10, an insulation layer 280 is arranged in a place that is between the outer edge portion and the first main electrode wiring 510 or the like that is to be connected to the first main electrode 100 (the connection conductor 20 in FIG. 2 to FIG. 4).

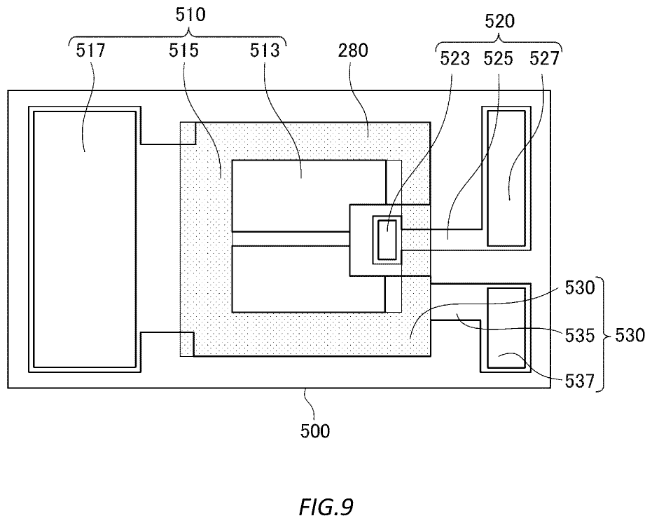

FIG. 9 shows a state in which an insulation layer 280 is arranged on the mounting substrate 210 according to the present embodiment. In the example of the present drawing, the insulation layer 280 is arranged by stacking the insulation layer 280 on a surface on a side in the first main electrode wiring 510 or the like that is closer to the switching device 10.

In the example of the present drawing, the insulation layer 280 is arranged in a region

that encloses the first main electrode contact 513 on the first main electrode wiring 510, in which a plurality of pillars 24 are formed. In the example of the present drawing, the insulation layer 280 is arranged by loading or affixing an insulation sheet that is to be the insulation layer 280 on the surface on the side in the first main electrode wiring 510 that is closer to the switching device 10.

In this process, by loading pieces of insulation sheets obtained by cutting a tape-like insulation sheet to be a required length along each side of an outer perimeter of the first main electrode contact 513, the insulation sheet may be arranged in a region that encloses a perimeter of the first main electrode contact 513. Alternatively, the insulation sheet of a shape that encloses the first main electrode contact 513 may be created and loaded in the connection conductor 20. Herein, for a place that does not face the connection conductor 20 such as the first main electrode wiring 510 at the outer edge portion of the switching device 10, the insulation layer 280 may not be arranged as long as a sufficient insulating property is obtained.

Note that on a surface of a side in the switching device 10 that is closer to a mounting substrate 210, an electrode such as the control electrode 110 in addition to the first main electrode 100 is provided. The insulation layer 280 may be arranged in a region that collectively encloses a perimeter of the control electrode contact 523 in a control wiring 520, in addition to the first main electrode contact 513.

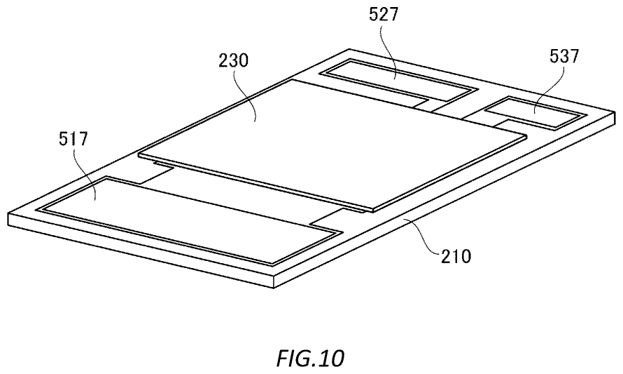

In S330, the switching device 10 is mounted on a mounting surface on which each wiring pattern on the mounting substrate 210 is formed. FIG. 10 is a perspective view of a configuration in which the switching device 10 to which the second main electrode plate 230 is bonded is bonded to the mounting substrate 210 according to the present embodiment. As shown in FIG. 7, the switching device 10 to which the second main electrode plate 230 is bonded is bonded to the mounting surface of the mounting substrate 210 with an upper surface of the switching device 10 of FIG. 7 facing downward. In this way, the first main electrode 100 of the switching device 10 is bonded to the first main electrode contact 513 of the first main electrode wiring 510 and the sub-wiring 530, and the control electrode 110 of the switching device 10 is bonded to the control electrode contact 523 of the control wiring 520. This bonding method may be similar to the bonding method of the second main electrode plate 230 for the second main electrode 120. This causes a state in which the insulation layer 280 is arranged between the outer edge portion of the switching device 10 and the connection conductor 20.

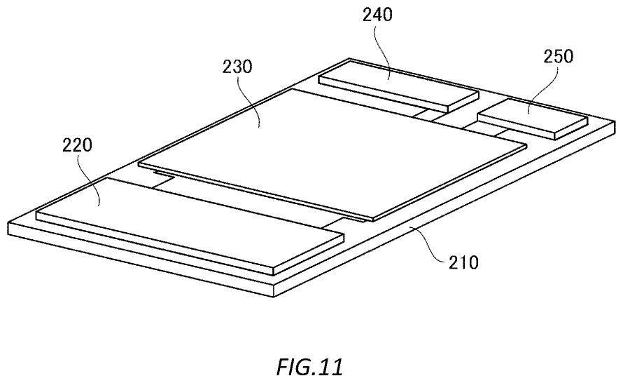

In S340, each electrode plate is bonded to each wiring of the mounting substrate 210. FIG. 11 is a perspective view of a configuration in which a first main electrode plate 220, a control electrode plate 240, and a sub-electrode plate 250 are bonded to the mounting substrate 210 according to the present embodiment. As shown in FIG. 11, a first main electrode plate contact 517 of a first main electrode wiring 510, a control electrode plate contact 527 of a control wiring 520, and a sub-electrode plate contact 537 of a sub-wiring 530 are positioned in a region on which a switching device 10 on a mounting surface on which a switching device 10 on a mounting substrate 210 is to be mounted is not arranged. In this process, a first main electrode plate 220, a control electrode plate 240, and a sub-electrode plate 250 are respectively bonded to such a first main electrode plate contact 517, a control electrode plate contact 527, and a sub-electrode plate contact 537. This bonding method may be similar to the bonding method of the second main electrode plate 230 for the second main electrode 120.

In this way, the first main electrode plate 220, the control electrode plate 240, and the sub-electrode plate 250 are positioned in a region in which the switching device 10 on the mounting surface of the switching device 10 is not arranged, and each of which is electrically connected to the first main electrode wiring 510, the control wiring 520, and the sub-wiring 530.

In this manner, a mounting substrate 210 having an insulating substrate 500, and the first main electrode wiring 510, the first main electrode plate 220, the control wiring 520, the control electrode plate 240, the sub-wiring 530, and the sub-electrode plate 250 formed on the insulating substrate 500 is made.

Herein, in the semiconductor device 200 according to the present embodiment, on the mounting surface of the switching device 10 in the mounting substrate 210, the switching device 10 is arranged between the first main electrode plate 220 and the control electrode plate 240. The sub-electrode plate 250 may be arranged on a same side as the control electrode plate 240 against the switching device 10. In this way, the semiconductor device 200 can take a configuration in which a wiring for controlling can be connected to the control electrode plate 240 and the sub-electrode plate 250 positioned on one end portion of the semiconductor device 200.

In S350, the semiconductor device 200 shown in FIG. 5 is obtained by forming an encapsulating portion 260 by encapsulating the mounting surface of the mounting substrate 210 with an encapsulant such that each electrode plate is exposed. Herein, the encapsulating portion 260 causes terminal surfaces of the first main electrode plate 220, the second main electrode plate 230, the control electrode plate 240, the sub-electrode plate 250, the semiconductor device 200 (upper surface in FIG. 2) to be exposed while coating a mounting surface of the switching device 10 in the mounting substrate 210 and a surface of a side in the switching device 10 that is closer to a mounting substrate 210. This encapsulating may be resin encapsulating by a molding material. By encapsulating the mounting surface of the mounting substrate 210, a space between the switching device 10 and the connection conductor 20 can be encapsulated by an encapsulation material. In this way, the semiconductor device 200 has a structure in which the encapsulating portion 260 and the insulation layer 280 are arranged to overlap with each other between the outer edge portion of the switching device 10 and the first main electrode wiring 510 (the conductor pattern 22 in FIG. 2 to FIG. 4).

In this process, after performing the encapsulating to coat the mounting surface of the switching device 10 on the mounting substrate 210 and the surface on the side in the switching device 10 that is closer to the mounting substrate 210, each electrode plate may be exposed by polishing a terminal surface of the semiconductor device 200 to reduce extra encapsulation material. The encapsulating process may be omitted in another embodiment, and the semiconductor device 200 may not include the encapsulating portion 260. Note that after this process, an antioxidant film may be formed by plating the exposed surface of each electrode plate with Sn or the like.

According to the manufacturing method described above, a semiconductor device 200 in which each terminal electrically connected to each electrode of the switching device 10 is exposed to one surface can be manufactured. Note that in the manufacturing method described above, the second main electrode plate 230 was bonded to the surface on the side of the switching device 10 that is closer to the second main electrode 120 in S310, however, this process may be omitted. In this case, the second main electrode 120 may be directly exposed to the terminal surface of the semiconductor device 200.

In addition, in the manufacturing method described above, the order of each process may be changed in a possible range. For example, S340 may be performed before S330, to mount the switching device 10 on the mounting substrate 210 after each electrode plate is bonded to each wiring of the mounting substrate 210. In addition, S310 may be performed after S330, to bond the second main electrode plate 230 to the surface on the side of the switching device 10 that is closer to the second main electrode 120 after mounting the mounting substrate 210 to the switching device 10. In addition, either of S300 and S310, and S320 may be performed earlier, or they may be performed in parallel.

Note that the semiconductor device 200 may include a temperature sensing diode for measuring the temperature of the semiconductor device 200 or the switching device 10, or another temperature sensor. In this case, the semiconductor device 200 may further have an electrode plate connected to an electrode of the temperature sensor such as an anode electrode and a cathode electrode of the temperature sensing diode on a same surface as that of the first main electrode plate 220 or the like, for example.

In addition, the number of the electrode plates arranged on the same surface as that of the first main electrode plate 220 or the like, and the magnitude, shape, and type or the like of each electrode plate in the semiconductor device 200 may be appropriately selected according to a usage form of the semiconductor device 200, and a temperature sensor, another additional circuit or the like that is added to the semiconductor device 200. For example, the semiconductor device 200 may reduce the area of the control electrode plate 240, and thereby a new electrode plate may be provided in the area in which a vacancy was occurred. Newly provided electrode plate includes at least one of, for example, a sensing electrode plate electrically connected to a sensing electrode 130, one or two or more temperature sensing electrode plates respectively connected to the electrodes of the temperature sensor such as the switching device 10 as described above, an electrode plate with a potential that is the same as that of the second main electrode plate 230 (sub-electrode plate or the like) or the like. In addition, for example, another electrode plate such as the second main electrode plate 230 may be extended to an area in which a vacancy is occurred by reducing the area of the control electrode plate 240.

Such an additional electrode may be used for measuring an electricity quantity for monitoring a state of the semiconductor device 200 or the switching device 10 or the like. Such an additional electrode may be arranged at a position apart from the first main electrode plate 220 and the second main electrode plate 230 and a flowing path of a large current such as a main wiring connected to these main electrode plates, such as in the vicinity of a side of the semiconductor device 200 that is closer to the side in which the control electrode plate 240 and the sub-electrode plate 250 are provided, for example. In this way, the semiconductor device 200 can reduce an impact applied on the additional electrodes due to at least one of the noise or heat occurred by the large current flowing.

In addition, another second sub-electrode plate that is different from the sub-electrode plate 250 may be provided in an area in which a vacancy is occurred by reducing the area of the control electrode plate 240, for example. The sub-electrode plate 250 (also indicated as a first sub-electrode plate) and the second sub-electrode plate may be arranged opposite sides of the control electrode plate 240 to sandwich the control electrode plate 240 between the sub-electrode plates. For forming such an arrangement, the mounting substrate 210 may have a second sub-wiring that electrically connects between the first main electrode 100 and the second sub-electrode plate of the switching device 10 on the mounting surface of the switching device 10, in addition to the sub-wiring 530. The sub-wiring 530 (also indicated as a first sub-wiring) and the second sub-wiring may be arranged on opposite sides of a control wiring 520 to sandwich the control wiring 520 between the sub-wirings. In this manner, by taking a configuration of sandwiching the control electrode plate 240 with two sub-electrode plates, the semiconductor device 200 can reduce a wiring inductance in a path through which a current for driving the semiconductor device 200 is flowing (that is, a current of a control signal flowing in the control electrode 110 of the switching device 10).

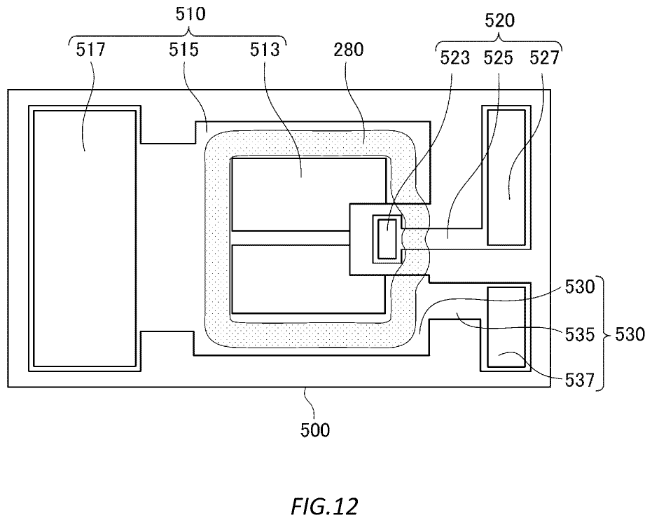

FIG. 12 shows a state in which an insulation layer 280 is arranged on the mounting substrate 210 according to a second modification example of the present embodiment. In S325 of FIG. 6, instead of loading the insulation sheet that is to be the insulation layer 280 as shown in FIG. 9 on the mounting substrate 210, the insulation layer 280 may be stacked on the surface on the side in the first main electrode wiring 510 or the like that is closer to the switching device 10 by the method shown in the present drawing.

In the example of the present drawing, an insulating material of liquid form that is to be the insulation layer 280 is applied on the surface on the side on the mounting substrate 210 that is closer to the switching device 10. Such an insulating material may be a polyimide material of a thermosetting type, as an example. After applying the insulating material on the surface on the side in the connection conductor 20 that is closer to the switching device 10, the insulation layer 280 may be formed by heating the mounting substrate 210 and performing thermal curing on the insulating material.

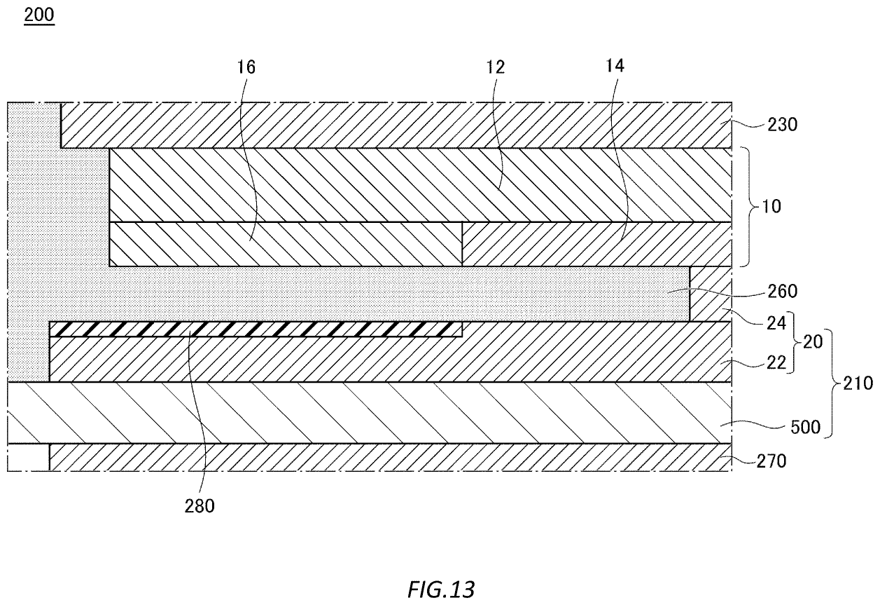

FIG. 13 is a cross section of a semiconductor device 200 according to a third modification example of the present embodiment. In a case in which the insulation layer 280 is formed by applying the insulating material in S325 of FIG. 6, the insulating material may spread to a region in which a plurality of pillars 24 are formed on the mounting substrate 210 (for example, the first main electrode contact 513 and the control electrode contact 523, or the like) depending on the amount and flowability of the insulating material. Therefore, a region that is connected to the first main electrode 100 in the connection conductor 20 such as the first main electrode wiring 510 and the control wiring 520 may have a structure that protrudes to a side closer to the first main electrode 100 against a region in which the insulation layer 280 is arranged. In this way, the connection conductor 20 can have a step between a region that is to be connected to the first main electrode 100 and a region in which the insulation layer 280 is to be arranged, which is for preventing the insulating material from spreading to the region that is to be connected to the first main electrode 100.

By providing such a step, the insulating material can be prevented from spreading to the region in which the plurality of pillars 24 are provided. In addition, by such a step, a range in which the insulation layer 280 is arranged can be defined more precisely.

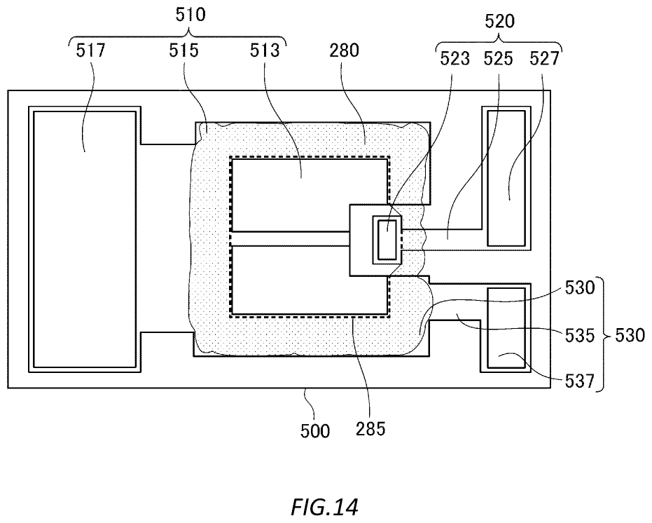

FIG. 14 shows a state in which an insulation layer 280 is arranged on the mounting substrate 210 according to a fourth modification example of the present embodiment. In the example of the present drawing, the connection conductor 20 such as the first main electrode wiring 510 and the control wiring 520 has a groove 285 that prevents the insulating material from spreading to the region that is to be connected to the first main electrode 100 and the control electrode 110 or the like, the groove 285 being positioned between a region such as the first main electrode contact 513 and the control electrode contact 523 that is to be connected to the first main electrode 100, the control electrode 110 and the like of the switching device 10 and a region such as the wiring 515 and the wiring 525 to which the insulation layer 280 is to be arranged. Such a groove 285 may be shallower compared to the thickness of the conductor pattern 22 in the connection conductor 20, and may not interrupt the conductivity of the connection conductor 20.

By providing such a groove 285, expansion of the insulating material to the region in which the plurality of pillars 24 are provided even if a little more insulating material is applied on the mounting substrate 210 can be reduced.

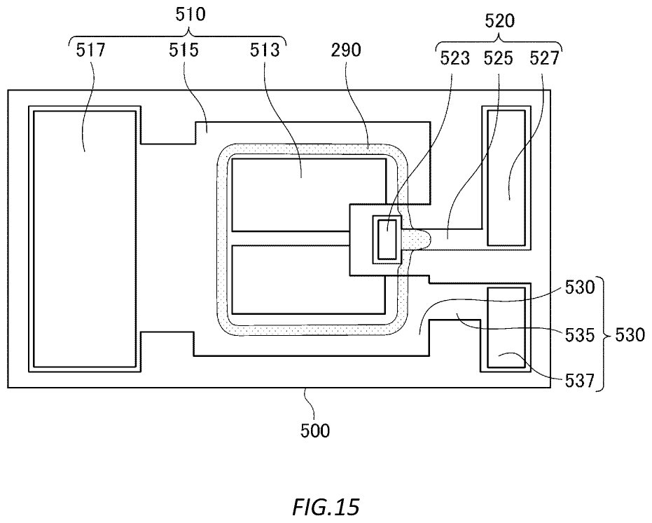

FIG. 15 shows a state in which a boundary wall 290 is arranged on the mounting substrate 210 according to a fifth modification example of the present embodiment. In the example of the present drawing, the applying the insulating material in S325 of FIG. 6 is performed separately by two or more times.

The present drawing shows a state in which a boundary wall 290 consisting of the insulating material is formed on a boundary between a region that is to be connected to a first main electrode 100 in the connection conductor 20 and a region on which an insulation layer 280 is to be arranged, by applying a part of the insulating material that is to be the insulation layer 280 on a surface on a side in the connection conductor 20 that is closer to a switching device 10 such as a first main electrode wiring 510 and a control wiring 520. When the boundary wall 290 is formed, the insulating material may be temporarily applied on a part of ½ or less or ¼ or less or the like of a region on which the insulation layer 280 is to be finally arranged. After applying a part of the insulating material in this manner, the boundary wall 290 is formed by performing thermal curing on the insulating material. In a case in which the insulating material has a viscosity that is high to some extent and functions as the boundary wall 290 even if the thermal curing is not performed, the thermal curing for forming the boundary wall 290 may be omitted.

After the boundary wall 290 is formed, the insulation layer 280 is formed by applying another part of the insulating material on a side closer to the region on which the insulation layer 280 is to be arranged with respect to the boundary wall 290. In this process, the insulating material applied on the side of the region on which the insulation layer 280 is to be arranged other than a side of a region on which the boundary wall 290 is positioned is dammed by the boundary wall 290. Accordingly, according to the present modification example, the insulating material can be prevented from spreading to the region that is to be connected to the first main electrode 100 in the connection conductor 20.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from description of the claims that the embodiments to which such alterations or improvements are made may be included in the technical scope of the present invention.

It should be noted that the operations, procedures, steps, stages, and the like of each process performed by an apparatus, system, program, and method shown in the claims, the specification, or the drawings can be realized in any order as long as the order is not indicated by “prior to,” “before,” or the like and as long as the output from a previous process is not used in a later process. Even if the operation flow is described using phrases such as “first” or “next” for the sake of convenience in the claims, the specification, or the drawings, it does not necessarily mean that the process must be performed in this order.

### EXPLANATION OF REFERENCES

10: switching device;
12: chip substrate;
14: metal film;
16: dielectric film;
20: connection conductor;
22: conductor pattern;
24: pillar;
100: first main electrode;
110: control electrode;
120: second main electrode;
130: sensing electrode;
200: semiconductor device;
210: mounting substrate;
220: first main electrode plate;
230: second main electrode plate;
240: control electrode plate;
250: sub-electrode plate;
260: encapsulating portion;
270: heat conductor plate;
280: insulation layer;
285: groove;
290: boundary wall;
500: insulating substrate;
510: first main electrode wiring;
513: first main electrode contact;
515: wiring;
517: first main electrode plate contact;
520: control wiring;
523: control electrode contact;
525: wiring;
527: control electrode plate contact;
530: sub-wiring;
535: wiring;
537: sub-electrode plate contact.

What is claimed is:

1. A semiconductor device, comprising:
a switching device having a first main electrode on one surface;
a connection conductor that is connected to the first main electrode of the switching device;
an encapsulating portion that encapsulates a space between the switching device and the connection conductor; and
an insulation layer arranged to overlap with the encapsulating portion between at least a part of the switching device and the connection conductor.

2. The semiconductor device according to claim 1, wherein the insulation layer has an electrical resistivity higher than that of an encapsulation material of the encapsulating portion.

3. The semiconductor device according to claim 1, wherein the insulation layer is stacked on a surface on a side in the connection conductor that is closer to the switching device.

4. The semiconductor device according to claim 3, wherein the insulation layer is arranged on a surface on the side in the connection conductor that is closer to the switching device to face a region including from at least a part of an outer edge portion in the switching device to an outer edge portion of a conductor exposed to a surface on a side of the switching device that is closer to the connection conductor.

5. The semiconductor device according to claim 3, wherein a region that is connected to the first main electrode in the connection conductor protrudes to a side closer to the first main electrode against a region in which the insulation layer is arranged.

6. The semiconductor device according to claim 3, wherein the connection conductor has a groove between a region that is connected to the first main electrode and a region in which the insulation layer is arranged.

7. The semiconductor device according to claim 1, wherein the insulation layer is stacked on a surface on a side in the switching device that is closer to the connection conductor.

8. The semiconductor device according to claim 1, wherein the connection conductor has a plurality of bumps contacting the first main electrode.

9. The semiconductor device according to claim 1, comprising a mounting substrate that has the connection conductor on a mounting surface on which the switching device is mounted, and a first main electrode plate that is connected to the connection conductor in a region in which the switching device on the mounting surface is not arranged.

10. The semiconductor device according to claim 9, comprising:
a second main electrode plate that is connected to a second main electrode of the switching device; wherein
the mounting substrate has a control electrode plate that is connected to a control electrode of the switching device; and
the first main electrode plate, the second main electrode plate, and the control electrode plate are exposed to one surface of the semiconductor device.

11. The semiconductor device according to claim 9, wherein the mounting substrate has a heat conductor plate that is formed on a surface on a side opposite to the mounting surface.

12. The semiconductor device according to claim 1, wherein the switching device is a power MOSFET, an IGBT, or a SiC semiconductor device.

13. A manufacturing method of a semiconductor device, comprising:
preparing a switching device having a first main electrode on one surface;
arranging an insulation layer in a place that is between at least a part of the switching device and a connection conductor that is to be connected to the first main electrode;
connecting the connection conductor to the first main electrode of the switching device; and
encapsulating a space between the switching device and the connection conductor by an encapsulation material.

14. The manufacturing method according to claim 13, wherein the arranging the insulation layer includes stacking the insulation layer on a surface on a side in the connection conductor that is closer to the switching device.

15. The manufacturing method according to claim 14, wherein the stacking the insulation layer on the surface on the side in the connection conductor that is closer to the switching device includes loading an insulation sheet that is to be the insulation layer on the surface on the side in the connection conductor that is closer to the switching device.

16. The manufacturing method according to claim 14, wherein the stacking the insulation layer on the surface on the side in the connection conductor that is closer to the switching device includes applying an insulating material that is to be the insulation layer on the surface on the side in the connection conductor that is closer to the switching device.

17. The manufacturing method according to claim 16, wherein the connection conductor has a step between a region that is to be connected to the first main electrode and a region in which the insulation layer is to be arranged, which is for preventing the insulating material from spreading to the region that is to be connected to the first main electrode.

18. The manufacturing method according to claim 16, wherein the connection conductor has a groove between a region that is to be connected to the first main electrode and a region in which the insulation layer is to be arranged, which is for preventing the insulating material from spreading to the region that is to be connected to the first main electrode.

19. The manufacturing method according to claim 16, wherein the applying the insulating material includes:
forming a boundary wall consisting of the insulating material on a boundary between a region that is to be connected to the first main electrode in the connection conductor and a region on which the insulation layer is to be arranged, by applying one part of the insulating material that is to be the insulation layer on the surface on the side in the connection conductor that is closer to the switching device; and
forming the insulation layer by applying another part of the insulating material on a side closer to a region on which the insulation layer is to be arranged with respect to the boundary wall.

20. The manufacturing method according to claim 16, wherein the insulation layer has an electrical resistivity higher than that of the encapsulation material.
